(19) United States
(12) Patent Application Publication
(10) Pub. No.: US 2025/0253130 A1
(43) Pub. Date: Aug. 7, 2025

(54) TEMPORAL CONTROL OF PLASMA PROCESSING

(71) Applicant: Applied Materials, Inc., Santa Clara, CA (US)

(72) Inventors: Yue GUO, Redwood City, CA (US); Sonam Dorje SHERPA, Santa Clara, CA (US); Alok RANJAN, Santa Clara, CA (US); Shreeram Jyoti DASH, San Jose, CA (US); Yang YANG, San Diego, CA (US); Kartik RAMASWAMY, San Jose, CA (US)

(21) Appl. No.: 18/432,955

(22) Filed: Feb. 5, 2024

(51) Int. Cl. H01J 37/32

(52) U.S. Cl. CPC H01J 37/32146; H01J 37/321; H01J 2237/327; H01J 2237/332

(57) ABSTRACT

Embodiments of the disclosure include apparatus (e.g., plasma processing systems) and methods for plasma processing. A first radio frequency (RF) signal is delivered from a source RF generator to a processing region of a plasma processing chamber during a first period of time. The first period of time ends at a beginning of a second period of time. A second RF signal is delivered from a bias RF generator to the processing region of the plasma processing chamber during the second period of time. The second period of time ends at a beginning of a third period of time. A pulsed voltage waveform is delivered from a voltage source to a first electrode disposed within the plasma processing chamber during the third period of time.

### BACKGROUND

### Field

Embodiments described herein generally relate to a system and methods used in semiconductor device fabrication. More specifically, embodiments of the present disclosure relate to a plasma processing system used to process a substrate.

### Description of the Related Art

Reliably producing high aspect ratio features is one of the key technology challenges for the next generation of semiconductor devices. One method of forming high aspect ratio features uses a plasma assisted etching process, such as a reactive ion etch (RIE) plasma process, to form high aspect ratio openings in a material layer, such as a dielectric layer, of a substrate. In a typical RIE plasma process, a plasma is formed in a processing chamber and ions from the plasma are accelerated towards a surface of a substrate to form openings in a material layer disposed beneath a mask layer formed on the surface of the substrate.

Ion energy control in plasma assisted etching processes is a challenge to the development of reliable and repeatable device formation processes in the semiconductor equipment industry. The need for precise ion energy control becomes more significant at smaller scales for smaller feature sizes. At these smaller scales, features produced by plasma assisted etching processes are inconsistent and unreliable.

Accordingly, there is a need in the art for a desirable plasma-assisted process that solves the problems described above.

### SUMMARY

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

Embodiments of the present disclosure provide a method for plasma processing. The method generally includes delivering a first radio frequency (RF) signal from a source RF generator to a processing region of a plasma processing chamber during a first period of time. The first period of time ends at a beginning of a second period of time. A second RF signal is delivered from a bias RF generator to the processing region during the second period of time. The second period of time ends a beginning of a third period of time. A pulsed voltage waveform is delivered from a voltage source to a first electrode disposed within the plasma processing chamber during the third period of time.

Embodiments of the present disclosure provide a non-transitory computer readable medium storing executable instructions that, when executed by at least one processor, cause the at least one processor to perform operations including delivering a first radio frequency (RF) signal from a source RF generator to a processing region of a plasma processing chamber during at least a portion of a first period of time, delivering a second RF signal from a bias RF generator to the processing region of the plasma processing chamber during at least a portion of a second period of time, and delivering a pulsed voltage waveform from a voltage source to a first electrode disposed in the plasma processing chamber during a third period of time. The first period of time ends at a beginning of the second period of time, and the second period of time ends at a beginning of the third period of time.

### BRIEF DESCRIPTION OF THE DRAWINGS

So that the manner in which the above recited features of embodiments of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A is a schematic representation of an example plasma processing system, in accordance with certain embodiments of the present disclosure.

FIG. 1B illustrates a graph of a voltage waveform that is established on a substrate due to a voltage waveform applied to an electrode within a processing chamber, in accordance with certain embodiments of the present disclosure.

FIG. 2 illustrates a graph of example inputs for controlling plasma processing during periods of time and corresponding example effects of controlling the plasma processing during the periods of time, in accordance with certain embodiments of the present disclosure.

FIGS. 3A, 3B, 3C, and 3D illustrate graphs of example inputs for controlling plasma processing during periods of time, in accordance with certain embodiments of the present disclosure.

FIG. 4 illustrates a graph of example inputs for controlling plasma processing during periods of time and corresponding example effects of controlling the plasma processing during the periods of time, in accordance with certain embodiments of the present disclosure.

FIGS. 5A, 5B, and, 5C illustrate graphs of example inputs for controlling plasma processing during periods of time, in accordance with certain embodiments of the present disclosure.

FIG. 6 illustrates a graph of example inputs for controlling plasma processing during periods of time and corresponding example effects of controlling the plasma processing during the periods of time, in accordance with certain embodiments of the present disclosure.

FIG. 7 illustrates a graph of example inputs for controlling plasma processing during periods of time and corresponding example effects of controlling the plasma processing during the periods of time, in accordance with certain embodiments of the present disclosure.

FIG. 8 is a flow diagram illustrating a method for plasma processing, in accordance with certain embodiments of the present disclosure.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present disclosure generally relate to apparatus and methods for performing plasma-assisted processes. More specifically, embodiments described herein provide for controlling a plasma during processing by temporally controlling delivery of a first radio frequency (RF) signal, a second RF signal, and a pulsed voltage waveform. In some embodiments, the first RF signal may be delivered to a processing region of a plasma processing chamber from a source RF generator. For example, a controller of a plasma processing system may cause the source RF generator to deliver the first RF signal to an RF coil of the plasma processing system during at least a portion of a first period of time. In one or more embodiments, the second RF signal can be delivered to the processing region of the plasma processing chamber by a bias RF generator. In certain examples, the controller may cause the bias RF generator to deliver the second RF signal to an electrode disposed in the plasma processing chamber during at least a portion of a second period of time. In various embodiments, the pulsed voltage waveform can be delivered to the processing region of the plasma processing chamber by a voltage source. In some examples, the controller causes the voltage source to deliver the pulsed voltage waveform to an additional electrode disposed in the plasma processing chamber during at least a portion of a third period of time. In certain embodiments, the first RF signal, the second RF signal, and the pulsed voltage waveform can each be delivered at multiple power levels, may overlap in time in whole or in part, such as the overlap can be delivered across multiple portions of the first, second, and third periods of time, etc. By controlling the delivery of the first RF signal, the second RF signal, and the pulsed voltage waveform in a temporal manner, ion energy control is improved, power instability is reduced, and parameters of the plasma processing system can be manipulated for performing particular steps in plasma assisted processes.

### Processing System Examples

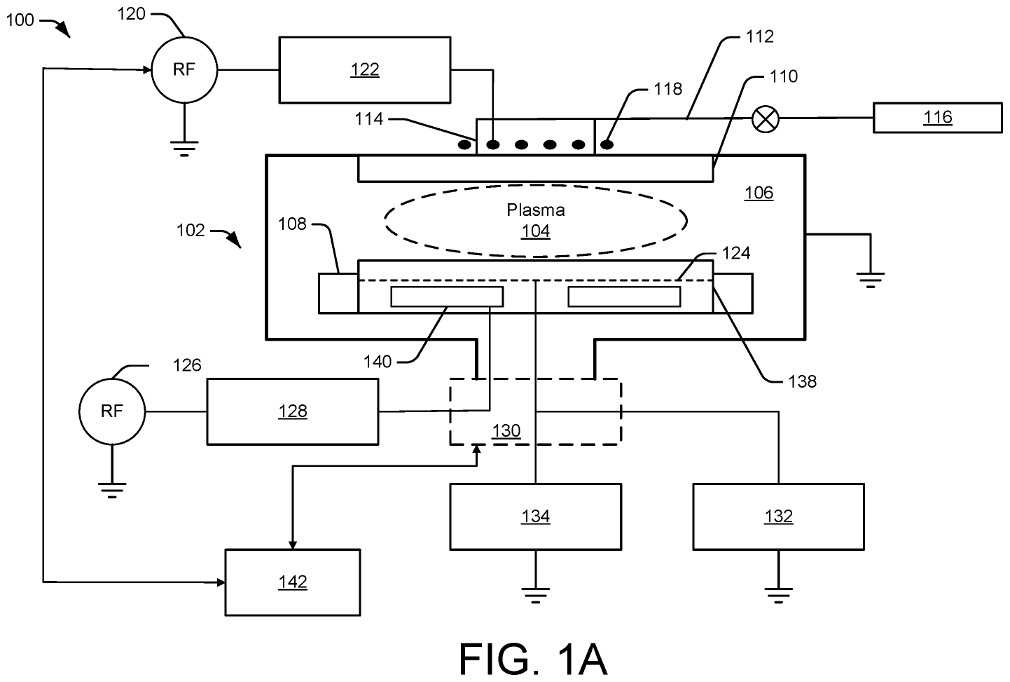

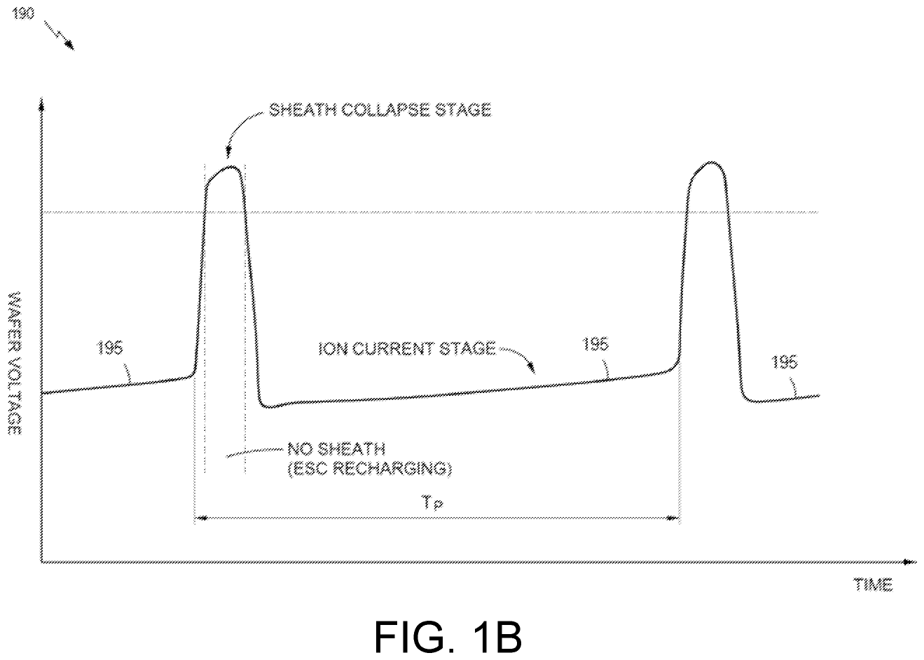

FIG. 1A is a schematic representation of an example plasma processing system 100. The plasma processing system 100 is configured for plasma-assisted etching processes, such as a reactive ion etch (RIE) plasma processing. The plasma processing system 100 can also be used in other plasma-assisted processes, such as plasma-enhanced chemical vapor deposition (PECVD) processes, plasma-enhanced physical vapor deposition (PEPVD) processes, plasma-enhanced atomic layer deposition (PEALD) processes, plasma treatment processing, plasma-based ion implant processing, or plasma doping processing. In some embodiments, as shown in FIG. 1A, the plasma processing system 100 is configured to generate a plasma using an inductively coupled plasma (ICP) source disposed over a processing region of the plasma processing system 100. In other embodiments, a plasma may alternately be generated by a capacitively-coupled-plasma (CCP) system.

The plasma processing system 100 includes a plasma processing chamber 102 which is illustrated to include a plasma 104 in a processing region 106 of the plasma processing chamber 102. The plasma 104 is disposed between a substrate support assembly 108 and a chamber lid 110 of the plasma processing chamber 102. The chamber lid 110 can include one or more sidewalls and a chamber base that are configured to withstand forces/pressures while the plasma 104 is generated within a vacuum environment maintained in the processing region 106 of the plasma processing chamber 102. In some CCP embodiments, the chamber lid 110 can be grounded to function as an upper electrode of the plasma processing system 100.

A gas delivery system 112 includes one or more gas inlets 114, and the gas delivery system 112 is coupled to the processing region 106 of the plasma processing chamber 102. The gas delivery system 112 is configured to deliver at least one processing gas (e.g., argon, nitrogen, oxygen, hydrogen, etc.) from at least one gas processing source 116 to the processing region 106 via the gas inlets 114 which extend through the chamber lid 110. Depending on the plasma process the processing gas can include at least one of an inert gas (e.g., helium, argon, nitrogen (N₂)) or dry etching gas (e.g., HBr, HF, HCl, CF₄, NF₃ or XeF₂). In some embodiments, the gas delivery system 112 can include components for activating or energizing one or more processing gasses before delivering the processing gasses to the processing region 106.

The plasma processing system 100 includes a radio frequency (RF) coil 118 configured to induce an oscillating electromagnetic field (e.g., a time varying magnetic field and a corresponding electric field) within the plasma processing chamber 102. Interactions of with the electric field induced by the RF coil 118 cause ionization of atoms/molecules of one or more gasses delivered to the processing region 106 by the gas delivery system 112. Ionizing the gas atoms/molecules forms a plasma state that is usable to initiate and/or maintain the plasma 104.

In order to induce the electromagnetic field within the plasma processing chamber 102, a source RF generator 120 delivers a first RF signal to the processing region 106 of the plasma processing chamber 102 during a first period of time. In some embodiments, the source RF generator 120 is electrically coupled to the RF coil 118 such that RF power generated by the source RF generator 120 can be delivered to the RF coil 118. A center frequency of power delivered by the source RF generator 120 may be from 13.56 MHz to the very high frequency band such as 40 MHz, 60 MHz, 120 MHz, or 162 MHz. The delivered power can be operated in a continuous mode or a pulsed mode. A pulsing frequency of the delivered power can be from 100 Hz to 10 KHz with duty cycles ranging from 5 percent to 95 percent. The source RF generator 120 has a frequency tuning capability and can adjust its delivered power frequency within e.g., ±5 percent or ±10 percent. In some embodiments, the source RF generator 120 switches the delivered power frequency at a predefined speed (e.g., two nanoseconds, fifty nanoseconds, etc.).

The source RF generator 120 delivers RF alternating current to the RF coil 118 which flows through the RF coil 118 and generates the time varying magnetic field. For instance, the time varying magnetic field induces the electric field which interacts with charged particles within one or more gasses delivered to the processing region 106 by the gas delivery system 112 causing the charged particles to gain energy. Some electrons gain enough energy to break free of atomic orbits which generates free electrons. These energized free electrons collide with neutral gas atoms/molecules causing the atoms/molecules to ionize by gaining/losing electrons. As a result, the plasma 104 forms as a mixture of free electrons, positive ions, and neutral atoms/molecules.

In some embodiments, an RF match 122 is disposed between the source RF generator 120 and the RF coil 118. For example, the RF match 122 is an electrical circuit disposed between the source RF generator 120 and a plasma reactor (e.g., the processing region 106 of the plasma processing chamber 102) for optimizing power delivery efficiency. In some embodiments, the RF match 122 is configured to match impedances of a source (e.g., the source RF generator 120) and a load by adjusting one or more components of the RF match 122 as the source and load impedances change. One or more RF filters (e.g., within the RF match 122) are designed to only pass signals in a selected frequency range, and to isolate RF power supplies from each other.

The plasma processing system 100 is illustrated to include a chucking electrode 124 (e.g., an electrostatic chuck) disposed in the substrate support assembly 108. The chucking electrode 124 is configured to immobilize and stabilize substrates/wafers during plasma processing using an electrostatic force between the chucking electrode 124 and the substrates/wafers. The electrostatic force is generated by applying a voltage to the chucking electrode 124 during the plasma processing. After the plasma processing, the substrates/wafers are released by halting the application of the voltage to the chucking electrode 124.

In some embodiments, the plasma processing system 100 includes a bias RF generator 126 configured to deliver a second RF signal to the processing region 106 of the plasma processing chamber 102 during a second period of time. An RF match 128 is disposed between the bias RF generator 126 and a junction-box 130. For example, the RF match 128 is configured to match impedances of a source (e.g., the bias RF generator 126) and a load by adjusting one or more components of the RF match 128 as the source and load impedances change. One or more RF filters (e.g., within the RF match 128) are designed to only pass signals in a selected frequency range, and to isolate RF power supplies from each other. In various embodiments, the RF match 122 and/or the RF match 128 may include one or more RF filters configured to electrically isolate the source RF generator 120 from the bias RF generator 126 and/or configured to electrically isolate the bias RF generator 126 from the source RF generator 120.

The junction-box 130 is configured to control or manage operations of components/subsystems (e.g., the bias RF generator 126) within the plasma processing system 100. For example, the junction-box 130 can supply power to different components of the plasma processing system 100 (e.g., the chucking electrode 124, the bias RF generator 126, etc.) and/or facilitate transmission of control signals or data between the different components of the plasma processing system 100. The junction-box 130 is electrically and/or communicatively coupled to the chucking electrode 124, the bias RF generator 126, a high voltage DC supply 132, and a waveform generator 134.

The high voltage DC supply 132 includes a voltage source capable of outputting example voltages of ±5000 V, ±10000 V, ±100000 V, etc. In some embodiments, the waveform generator 134 generates a pulsed waveform, and the junction-box 130 controls an integration of the waveform generator 134 and the high voltage DC supply 132 to deliver a pulsed voltage (PV) waveform from a voltage source (e.g., the waveform generator 134 and the high voltage DC supply 132) to a chucking electrode 124 disposed within the plasma processing chamber 102 during a third period of time. In some embodiments, the waveform generator 134 and the high voltage DC supply 132 are electrically coupled to the chucking electrode 124 via the junction-box 130. The bias RF generator 126 and the RF match 128 can be electrically coupled to a first electrode 140 via the junction-box 130. The first electrode 140 may be disposed within a substrate support 138 of the plasma processing chamber 102.

FIG. 1B illustrates a graph 190 of a typical voltage waveform established at a substrate disposed on the substrate supporting surface (e.g., upper surface) of the substrate support assembly 108 of the plasma processing system 100 due to the delivery of PV waveforms to the chucking electrode 124 of the plasma processing system 100 by the waveform generator 134. A first waveform (e.g., a PV waveform 195) is an example of a non-compensated PV waveform established at the substrate during plasma processing. The PV waveform cycle of the waveform 195 has a period Tₚ, which is, for example, typically between 2 microsecond (μs) and 10 μs, such as 2.5 μs. The ion current stage of the PV waveform cycle will typically take up between about 50% and about 95% of the period Tₚ, such as from about 80% to about 90% of the period Tₚ.

The PV waveform 195 includes two main stages: an ion current stage and a sheath collapse stage. Both portions (e.g., the ion current stage and the sheath collapse stage) of the waveforms 195, can be alternately and/or separately established at the substrate during the plasma processing. At a beginning of the ion current stage, a drop in the voltage at the substrate is created, due to the delivery of a negative portion of the PV waveform (e.g., the ion current portion) provided to the chucking electrode 124 by the waveform generator 134, which creates a high voltage sheath above the substrate. The high voltage sheath allows the plasma generated positive ions to be accelerated towards the biased substrate during the ion current stage, and thus, for RIE processes, controls the amount and characteristics of the etching process that occurs on the surface of the substrate during the plasma processing. The sheath collapse stage includes a positive voltage swing (e.g., as a result of the positive wafer voltage), and the ion current stage includes a negative voltage swing (e.g., as a result of the positive wafer voltage), as illustrated in FIG. 1B.

The plasma processing system 100 is illustrated to include a controller 142 which includes a computing device having one or more processors, memory, and storage. The one or more processors can include central processing units, graphics processing units, accelerators, etc. The memory includes main memory for storing instructions for the one or more processors to execute or data for the one or more processors to operate on. For example, the memory includes random access memory (RAM). The storage includes mass storage for data or instructions. As an example and not by way of limitation, the storage may include a removable disk drive, flash memory, an optical disc, a magneto-optical disc, magnetic tape, or a Universal Serial Bus drive or two or more of these. The storage may include removable or fixed media and may be internal or external to the computing device. The storage may include any suitable form of non-volatile, solid-state memory, or read-only memory. The controller 142 includes a non-transitory computer readable medium or media. The non-transitory computer readable medium or media may include one or more semiconductor-based or other integrated circuits (ICs) (such, as for example, field-programmable gate arrays or application-specific ICs), hard disk drives, hybrid hard drives, optical discs, optical disc drives, magneto-optical discs, magneto-optical drives, solid-state drives, RAM drives, any other suitable non-transitory computer readable storage medium/media, or any suitable combination. The non-transitory computer readable medium or media may be volatile, non-volatile, or a combination of volatile and non-volatile. The controller 142 can be communicatively/electrically coupled to the source RF generator 120 and/or the junction-box 130 (e.g., the controller 142 may be communicatively/electrically coupled to the bias RF generator 126, the waveform generator 134, and/or the high voltage DC supply 132).

In the illustrated example in which the plasma processing system 100 includes the source RF generator 120, the bias RF generator 126, and the voltage source (e.g., the waveform generator 134 and the high voltage DC supply 132), the plasma processing system 100 is capable of temporal control (e.g., via the controller 142) of the plasma 104 for plasma processing. For example, the source RF generator 120 delivers the first RF signal to the RF coil 118 during the first period of time which ends at a beginning of the second period of time. The bias RF generator 126 may deliver the second RF signal to the first electrode 140 during the second period of time which ends at a beginning of the third period of time. The voltage source (e.g., the waveform generator 134) can deliver the pulsed voltage waveform to the chucking electrode 124 during the third period of time. By selectively delivering the first RF signal, the second RF signal, and/or the pulsed voltage waveform to the processing region 106, characteristics of the plasma 104 (e.g., an ion to radical ratio) can be precisely controlled during the first, second, and third periods of time. This precise control may be utilized to reduce power instability and/or increase flexibility of the plasma processing system 100.

### Temporal Control Examples

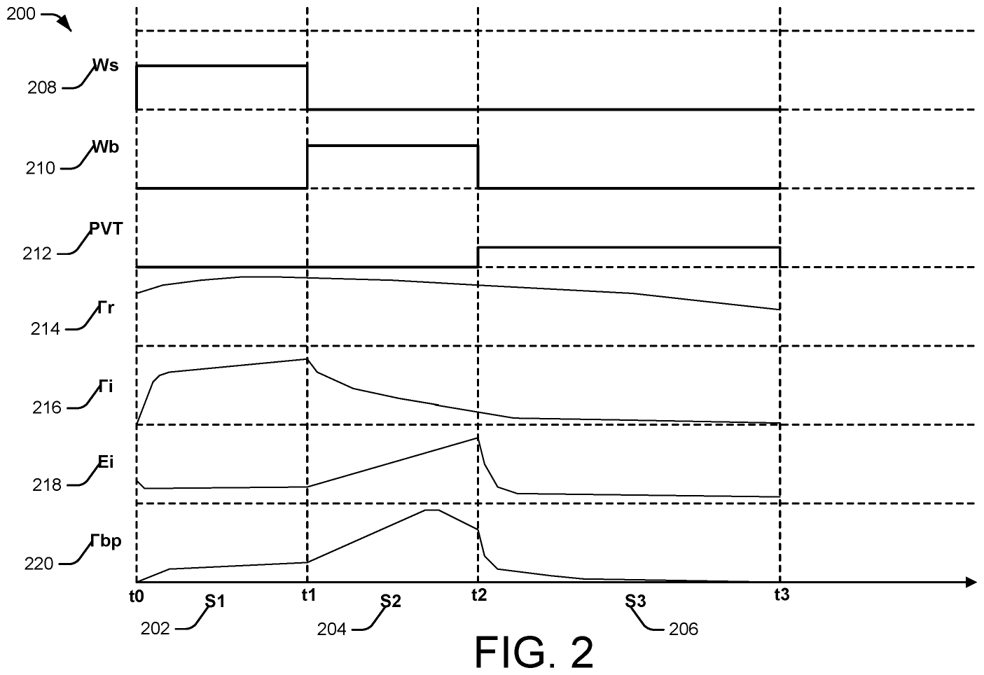

FIG. 2 illustrates a graph 200 of example inputs for controlling plasma processing during periods of time and corresponding example effects of controlling the plasma processing during the periods of time. The x-axis of the graph 200 includes a first period of time 202, a second period of time 204, and a third period of time 206. In some embodiments, the first period of time 202 may correspond to a plasma and radical generation step of a plasma assisted etching process. In one or more embodiments, the second period of time 204 corresponds to an etching step of the plasma assisted etching process. In various embodiments, the third period of time 206 corresponds to a byproduct removal and surface pretreatment step of the plasma assisted etching process. As shown, the first period of time 202 begins at to and ends at t1. The second period of time 204 begins at t1 and ends at t2. The third period of time 206 begins at t2 and ends at t3. Notably, the first period of time 202, the second period of time 204, and the third period of time 206 may be repeated one or more times (e.g., in a loop).

The y-axis of the graph 200 includes a first input 208, a second input 210, and a third input 212. The first input 208 represents the first radio frequency (RF) signal delivered by the source RF generator 120 to the processing region 106 (e.g., to the RF coil 118). The second input 210 represents the second RF signal delivered by the bias RF generator 126 to the processing region 106 (e.g., to the first electrode 140). The third input 212 represents the pulsed voltage waveform (e.g., PV waveform 195) delivered from the voltage source (e.g., the waveform generator 134) to the processing region 106 (e.g., to the chucking electrode 124). In some embodiments of the disclosure, the first input includes an RF signal that has a first power level that is between 0 and 4,000 Watts, such as between 1 Watt and 4,000 Watts, the second input includes an RF signal that has a second power level that is between 0 and 10,000 Watts, such as between 1 Watt and 10,000 Watts, and the third input includes a voltage waveform that has a voltage magnitude (i.e., positive or negative volts) that is between zero volts (V) and about 10,000 V, such as between 1 V and 10,000 V. In some embodiments, the RF signals can include a sinusoidal waveform that is a frequency between about 1 MHz and 162 MHZ, while the third input may include a non-sinusoidal voltage waveform.

The y-axis of the graph 200 also includes a radical flux 214 in the plasma processing chamber 102, an ion flux 216 in the plasma processing chamber 102, an ion energy 218 in the plasma processing chamber 102, and a byproduct flux 220 in the plasma processing chamber 102. During the first period of time 202, the first input 208 is delivered to the processing region 106. For example, the controller 142 causes the source RF generator 120 to deliver the first RF signal to the processing region 106 during the first period of time 202. Also during the first period of time 202, the second input 210 and the third input 212 are not delivered to the processing region 106. As shown in the graph 200, during the first period of time 202, due to the delivery of the first RF signal within the first input 208 to the RF coil 118, the radical flux 214 and the ion flux 216 will be relatively high while the ion energy 218 and the byproduct flux 220 are relatively low.

At t1, the first period of time 202 ends and the second period of time 204 begins. During the second period of time 204, delivery of the first input 208 to the processing region 106 is halted (e.g., by the controller 142) and the second input 210 is delivered to the processing region 106. The third input 212 is not delivered to the processing region 106 during the second period of time 204. During the second period of time 204, due to the delivery of the second RF signal within the second input 210 to the first electrode 140, the radical flux 214 remains relatively high while the ion flux 216 decreases by a relatively large amount. Also during the second period of time 204, the ion energy 218 and the byproduct flux 220 both increase by relatively large amounts.

At t2, the second period of time 204 ends and the third period of time 206 begins. During the third period of time 206, delivery of the second input 210 to the processing region 106 is halted (e.g., by the controller 142) and the third input 212 is delivered to the processing region 106. The first input 208 is not delivered to the processing region 106 during the third period of time 206. During the third period of time 206, due to the delivery of the pulsed voltage waveform within the third input 212, the radical flux 214 decreases somewhat but remains moderately high at t3 when the third period of time 206 ends. The ion flux 216 starts low and ends lower during the third period of time 206. During the third period of time 206, both the ion energy 218 and the byproduct flux 220 decrease by relatively large amounts.

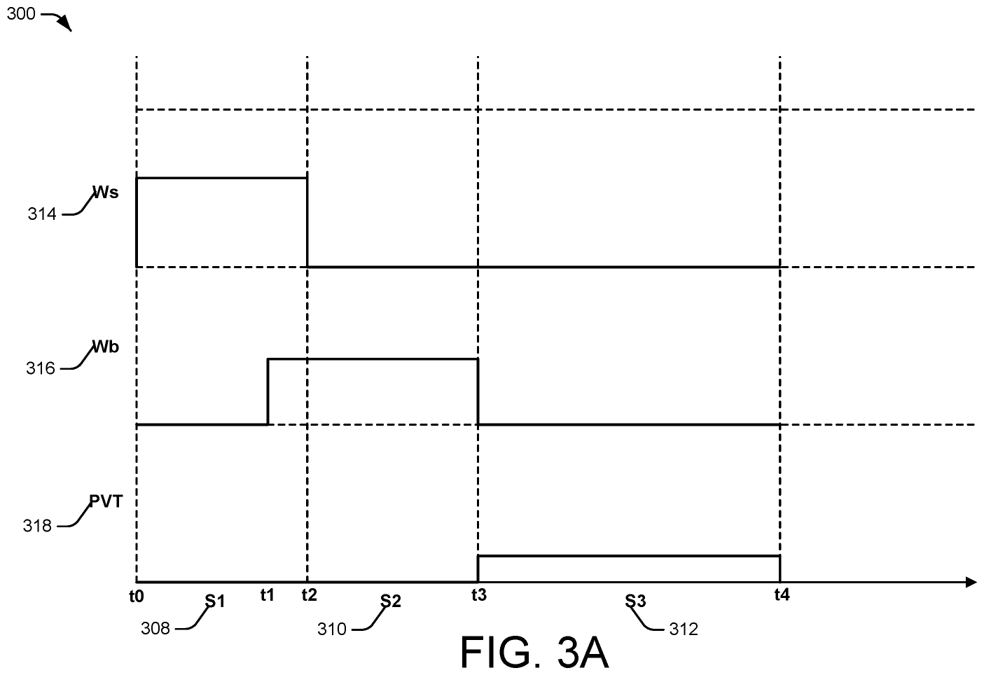

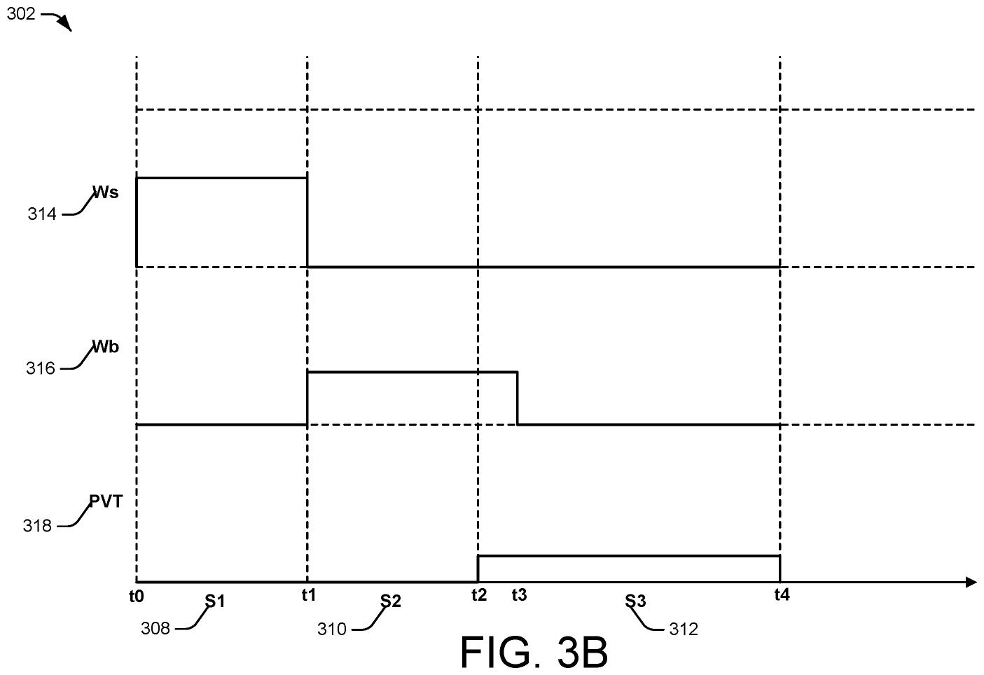

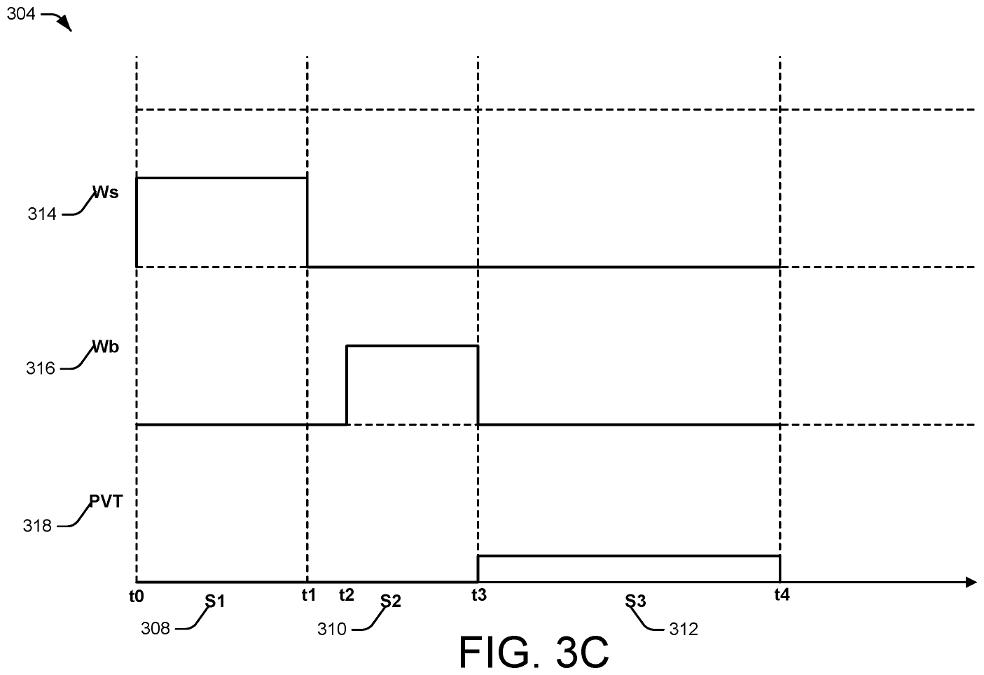

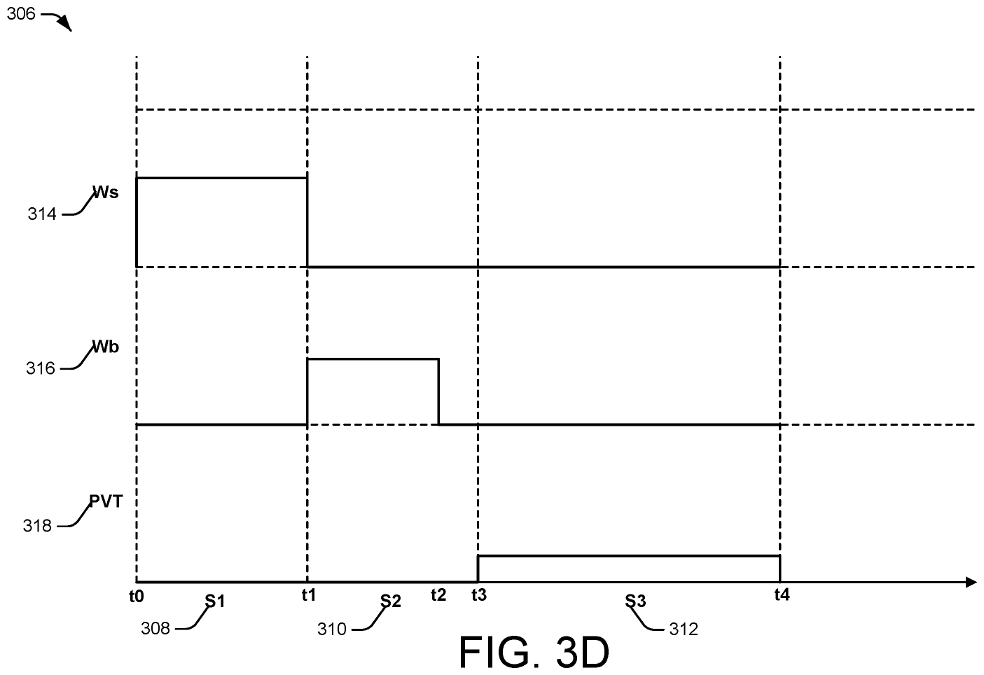

FIGS. 3A, 3B, 3C, and 3D illustrate graphs of example inputs for controlling plasma processing during periods of time. FIG. 3A illustrates a first graph 300; FIG. 3B illustrates a second graph 302; FIG. 3C illustrates a third graph 304; and FIG. 3D illustrates a fourth graph 306. The x-axis of the first graph 300 includes a first period of time 308, a second period of time 310, and a third period of time 312. In the first graph 300, the first period of time 308 begins at t0 and ends at t2. The second period of time 310 begins at t2 and ends at t3, and the third period of time 312 begins at t3 and ends at t4. In some embodiments, the first period of time 308 can be between 1 microsecond and 10 milliseconds long, the second period of time 310 can be between 1 microsecond and 10 milliseconds long, and the third period of time 312 can be between 1 microsecond and 10 milliseconds long.

The y-axis of the first graph 300 includes a first input 314, a second input 316, and a third input 318. In some embodiments, the first input 314 represents the first radio frequency (RF) signal delivered by the source RF generator 120 to the processing region 106 (e.g., to the RF coil 118). The second input 316 may represent the second RF signal delivered by the bias RF generator 126 to the processing region 106 (e.g., to the first electrode 140). The third input 212 can represent the pulsed voltage waveform (e.g., PV waveform 195) delivered from the voltage source (e.g., the waveform generator 134) to the processing region 106 (e.g., to the chucking electrode 124).

During the first period of time 308, the first input 314 is delivered to the processing region 106 from t0 to t2, and delivery of the first input 314 to the processing region 106 is halted at t2. The third input 318 is not delivered to the processing region 106 during the first period of time 308. The second input 316 is not delivered to the processing region 106 during a first portion of the first period of time 308, and the second input 316 is delivered to the processing region 106 during a second portion of the first period of time 308. In some embodiments, the first portion of the first period of time 308 can be between 1 microsecond and 10 milliseconds long and the second portion of the first period of time 308 can be between 1 microsecond and 10 milliseconds long. For example, the second input 316 is not delivered to the processing region 106 between t0 and t1. At t1, the second input 316 is delivered to the processing region 106 and this delivery continues during the second period of time 310.

During the second period of time 310, the first input 314 and the third input 318 are not delivered to the processing region 106. The second input 316 is delivered to the processing region 106 before the second period of time 310 and during the second period of time 310. Delivery of the second input 316 to the processing region 106 is halted (e.g., by the controller 142) at the beginning of the third period of time 312. The third input 318 is delivered to the processing region 106 (e.g., the chucking electrode 124) during the third period of time 312, and delivery of the third input 318 to the processing region 106 is halted at t4.

In the second graph 302 (FIG. 3B), the x-axis includes the first period of time 308, the second period of time 310, and the third period of time 312. The first period of time 308 is illustrated to begin at t0 and end at t1, the second period of time 310 is illustrated to begin at t1 and end at t2, and the third period of time 312 is illustrated to begin at t2 and end at t4. The y-axis of the second graph 302 includes the first input 314, the second input 316, and the third input 318. As shown in the second graph 302, the first input 314 is delivered to the processing region 106 (e.g., the RF coil 118) during the first period of time 308, and this delivery is halted at t1. The second input 316 and the third input 318 are not delivered to the processing region 106 during the first period of time 308.

During the second period of time 310, the first input 314 and the third input 318 are not delivered to the processing region 106. The second input 316 is delivered to the processing region 106 (e.g., the first electrode 140) during the second period of time 310 beginning at t1. The delivery of the second input 316 to the processing region 106 is not halted until t3 which occurs during the third period of time 312. In some embodiments, the overlap of the second input 316 and the delivery of the third input 318 during the third period of time 312 can be between 1 microsecond and 10 milliseconds long, and the third period of time 312 can be between 1 microsecond and 10 milliseconds long. During the third period of time 312, the first input 314 is not delivered to the processing region 106. The third input 318 is delivered to the processing region 106 (e.g., the chucking electrode 124) during the third period of time 312. The delivery of the third input 318 to the processing region 106 is halted (e.g., by the controller 142) at t4.

The x-axis of the third graph 304 (FIG. 3C) includes the first period of time 308, the second period of time 310, and the third period of time 312, and the y-axis of this graph includes the first input 314, the second input 316, and the third input 318. In the third graph 304, the first period of time 308 begins at t0 and ends at t1, the second period of time 310 begins at t1 and ends at t3, and the third period of time 312 begins at t3 and ends at t4. The first input 314 is delivered to the processing region 106 during the first period of time 308. The second input 316 and the third input 318 are not delivered to the processing region 106 during the first period of time 308.

The first input 314 and the third input 318 are not delivered to the processing region 106 during the second period of time 310. The second input 316 is not delivered to the processing region 106 during a first portion of the second period of time 310, and the second input 316 is delivered to the processing region 106 during a second portion of the second period of time 310. For example, the second input 316 is delivered to the processing region 106 beginning at t2 and this delivery is halted (e.g., by the controller 142) at t3. In some embodiments, the first portion of the second period of time 310 can be between 1 microsecond and 10 milliseconds long and the second portion of the second period of time 310 can be between 1 microsecond and 10 milliseconds long. The third input 318 is delivered to the processing region 106 during the third period of time 312. The first input 314 and the second input 316 are not delivered to the processing region 106 during the third period of time 312.

The y-axis of the fourth graph 306 (FIG. 3D) includes the first input 314, the second input 316, and the third input 318. The x-axis of the fourth graph 306 includes the first period of time 308, the second period of time 310, and the third period of time 312. The first period of time 308 begins at to and ends at t1, the second period of time 310 begins at t1 and ends at t3, and the third period of time 312 begins at t3 and ends at t4.

The first input 314 is delivered to the processing region 106 during the first period of time 308, and this delivery is halted (e.g., by the controller 142) at t1. The second input 316 and the third input 318 are not delivered to the processing region 106 during the first period of time 308. During the second period of time 310, the first input 314 and the third input 318 are not delivered to the processing region 106. The second input 316 is delivered to the processing region 106 (e.g., the first electrode 140) during a first portion of the second period of time 310. The second input 316 is not delivered to the processing region 106 during a second portion of the second period of time 310. For example, the second input 316 is delivered to the processing region 106 beginning at t1. The delivery of the second input 316 to the processing region 106 is halted at t2. In some embodiments, the first portion of the second period of time 310 can be between 1 microsecond and 10 milliseconds long and the second portion of the second period of time 310 can be between 1 microsecond and 10 milliseconds long. The third input 318 is delivered to the processing region 106 during the third period of time 312. The first input 314 and the second input 316 are not delivered to the processing region 106 during the third period of time 312.

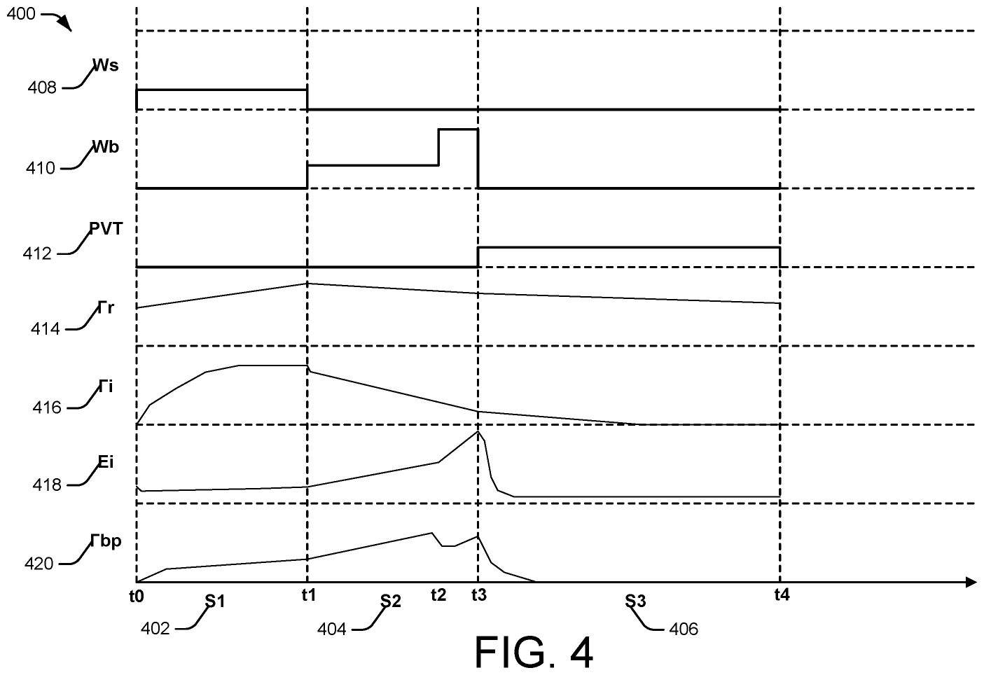

FIG. 4 illustrates a graph 400 of example inputs for controlling plasma processing during periods of time and corresponding example effects of controlling the plasma processing during the periods of time. The x-axis of the graph 400 includes a first period of time 402, a second period of time 404, and a third period of time 406. The first period of time 402 may correspond to a plasma and radical generation step of a plasma assisted etching process; the second period of time 404 can correspond to an etching step of the plasma assisted etching process; and the third period of time 406 may correspond to a byproduct removal and surface pretreatment step of the plasma assisted etching process. As shown, the first period of time 402 begins at t0 and ends at t1. The second period of time 404 begins at t1 and ends at t3. The third period of time 406 begins at t3 and ends at t4. In some embodiments, the first period of time 402, the second period of time 404, and the third period of time 406 may be repeated one or more times (e.g., in a loop).

The y-axis of the graph 400 includes a first input 408, a second input 410, and a third input 412. The first input 408 represents the first radio frequency (RF) signal delivered by the source RF generator 120 to the processing region 106 (e.g., to the RF coil 118). The second input 410 represents the second RF signal delivered by the bias RF generator 126 to the processing region 106 (e.g., to the first electrode 140). The third input 412 represents the pulsed voltage waveform (e.g., PV waveform 195) delivered from the voltage source (e.g., the waveform generator 134) to the processing region 106 (e.g., to the chucking electrode 124).

The y-axis of the graph 400 also includes a radical flux 414 in the plasma processing chamber 102, an ion flux 416 in the plasma processing chamber 102, an ion energy 418 in the plasma processing chamber 102, and a byproduct flux 420 in the plasma processing chamber 102. During the first period of time 402, the first input 408 is delivered to the processing region 106. The second input 410 and the third input 412 are not delivered to the processing region 106 during the first period of time 402. Due to the delivery of the first RF signal within the first input 408 to the RF coil 118, the radical flux 414 increases linearly and the ion flux 416 increases exponentially during the first period of time 402. The ion energy 418 and the byproduct flux 420 are each relatively low during the first period of time 402.

During the second period of time 404, the first input 408 and the third input 412 are not delivered to the processing region 106. The second input 410 is delivered to the processing region 106 at a first power level for a first portion of the second period of time 404, and the second input 410 is delivered to the processing region 106 at a second power level for a second portion of the second period of time 404. For example, the second input 410 is delivered to the processing region 106 at the first power level from t1 to t2. At t2, the second input 410 is delivered to the processing region 106 at the second power level which is illustrated to be greater than the first power level. At t3, the delivery of the second input 410 to the processing region 106 is halted (e.g., by the controller 142). During the second period of time 404, due to the delivery of the multi-power level second RF signal within the second input 410 to the first electrode 140, the radical flux 414 decreases by a relatively small amount and the ion flux 416 decreases by a relatively large amount. The ion energy 418 increases by a relatively large amount during the second period of time 404. The byproduct flux 420 increases by a moderate amount during the second period of time 404; however, the byproduct flux 420 decreases by a relatively small amount around t2.

During the third period of time 406, the third input 412 is delivered to the processing region 106. The first input 408 and the second input 410 are not delivered to the processing region 106 during the third period of time 406. During the third period of time 406, due to the delivery of the voltage waveform within the third input 412 to the chucking electrode 124, the radical flux 414 and the ion flux 416 decrease by relatively small amounts. The ion energy 418 and the byproduct flux 420 decrease by relatively large amounts during the third period of time 406.

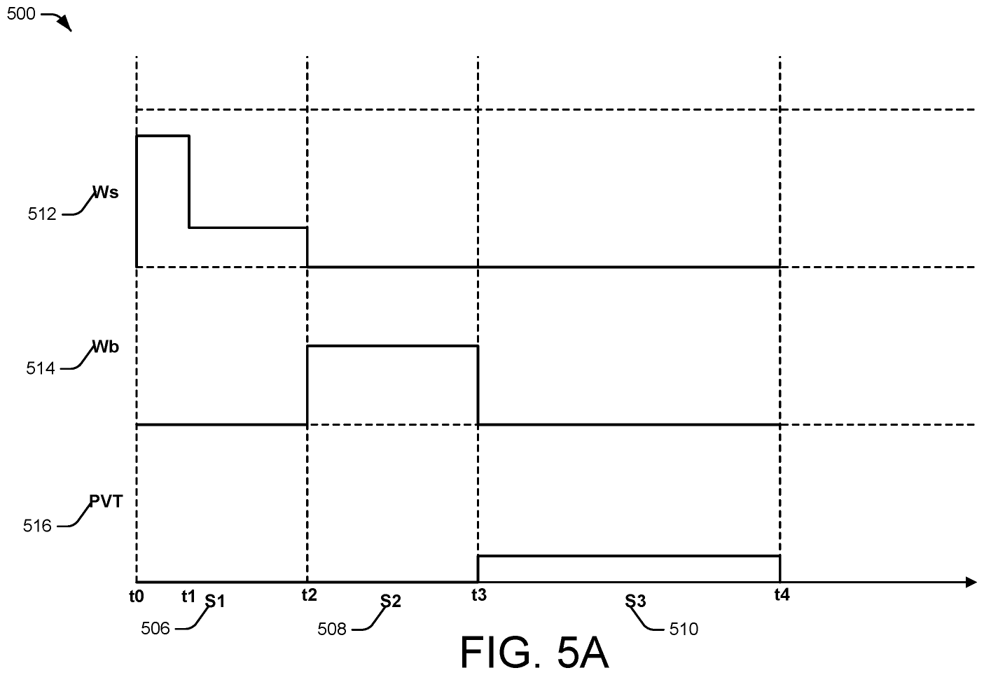

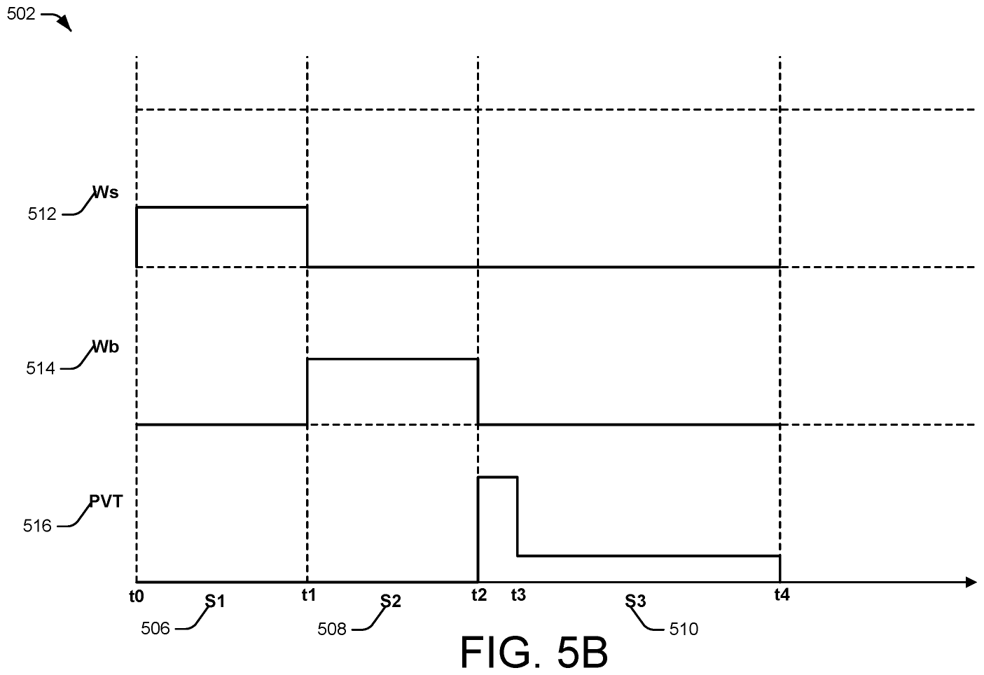

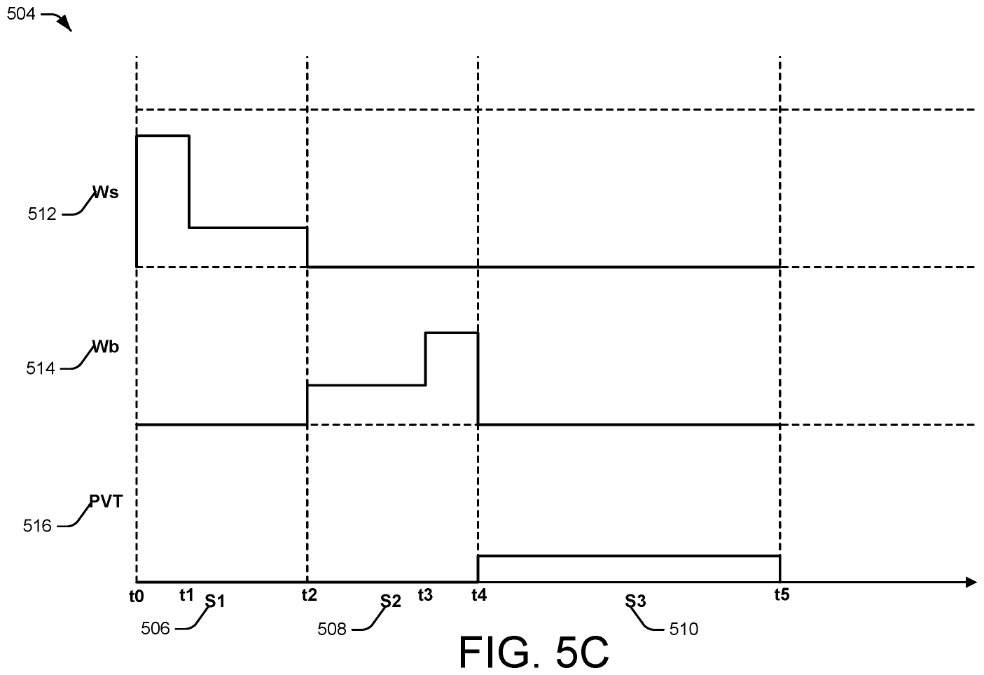

FIGS. 5A, 5B, and, 5C illustrate graphs of example inputs for controlling plasma processing during periods of time. FIG. 5A illustrates a first graph 500; FIG. 5B illustrates a second graph 502; and FIG. 5C illustrates a third graph 504. The x-axes of the first, second, and third graphs 500, 502, 504 include a first period of time 506, a second period of time 508, and a third period of time 510. The y-axes of the first, second, and third graphs 500, 502, 504 include a first input 512, a second input 514, and a third input 516. The first input 512 represents the first radio frequency (RF) signal delivered by the source RF generator 120 to the processing region 106 (e.g., to the RF coil 118). The second input 514 represents the second RF signal delivered by the bias RF generator 126 to the processing region 106 (e.g., to the first electrode 140). The third input 516 represents the pulsed voltage waveform (e.g., PV waveform 195) delivered from the voltage source (e.g., the waveform generator 134 and the high voltage DC supply 132) to the processing region 106 (e.g., to the chucking electrode 124).

In the first graph 500 (FIG. 5A), the first period of time 506 begins at to and ends at t2, the second period of time 508 begins at t2 and ends at t3, and the third period of time 510 begins at t3 and ends at t4. In some embodiments, the first period of time 506 can be between 1 microsecond and 10 milliseconds long, the second period of time can be between 1 microsecond and 10 milliseconds long, and the third period of time can be between 1 microsecond and 10 milliseconds long. The first input 512 is delivered to the processing region 106 at a first power level for a first portion of the first period of time 506. The first input 512 is delivered to the processing region 106 at a second power level for a second portion of the first period of time 506. In some embodiments, the first portion of the first period of time 506 can be between 1 microsecond and 10 milliseconds long and the second portion of the first period of time 506 can be between 1 microsecond and 10 milliseconds long. For example, the first input 512 is delivered to the processing region 106 at the first power level between t0 and t1. The first power level is illustrated to be greater than the second power level, and the first input 512 is delivered to the processing region 106 at the second power level between t1 and t2. In some embodiments, the first power level can be between 1 and 4,000 Watts and the second power level can be between 1 and 500 Watts. The second input 514 and the third input 516 are not delivered to the processing region 106 during the first period of time 506.

During the second period of time 508, the second input 514 is delivered to the processing region 106 (e.g., the first electrode 140). The first input 512 and the third input 516 are not delivered to the processing region 106 during the second period of time 508. During the third period of time 510, the third input 516 is delivered to the processing region 106 (e.g., the chucking electrode 124). The first input 512 and the second input 514 are not delivered to the processing region 106 during the third period of time 510.

In the second graph 502 (FIG. 5B), the first period of time 506 begins at t0 and ends at t1, the second period of time 508 begins at t1 and ends at t2, and the third period of time 510 begins at t2 and ends at t4. During the first period of time 506, the first input 512 is delivered to the processing region 106. The second input 514 and the third input 516 are not delivered to the processing region 106 during the first period of time 506. In the second period of time 508, the second input 514 is delivered to the processing region 106. The first input 512 and the third input 516 are not delivered to the processing region 106 during the second period of time 508.

The third input 516 is delivered to the processing region 106 at a first voltage magnitude for a first portion of the third period of time 510, and the third input 516 is delivered to the processing region 106 at a second voltage magnitude for a second portion of the third period of time 510. In some embodiments, the first portion of the third period of time 510 can be between 1 microsecond and 10 milliseconds long and the second portion of the third period of time 510 can be between 1 microsecond and 10 milliseconds long. For example, the third input 516 is delivered to the processing region 106 at the first voltage magnitude between t2 and t3. The third input 516 is delivered to the processing region 106 at the second voltage magnitude between t3 and t4. The second voltage magnitude is illustrated to be less than the first voltage magnitude. In some embodiments, the first voltage magnitude can be between 1 and 10,000 Volts and the second voltage magnitude can be between 1 and 3,000 Volts. The first input 512 and the second input 514 are not delivered to the processing region 106 during the third period of time 510.

In the third graph 504 (FIG. 5C), the first period of time 506 begins at to and ends at t2, the second period of time 508 begins at t2 and ends at t4, and the third period of time 510 begins at t4 and ends at t5. The second input 514 and the third input 516 are not delivered to the processing region 106 during the first period of time 506. The first input 512 is delivered to the processing region 106 at a first power level for a first portion of the first period of time 506. The first input 512 is delivered to the processing region at a second power level for a second portion of the first period of time 506. In some embodiments, the first portion of the first period of time 506 can be between 1 microsecond and 10 milliseconds and the second portion of the first period of time 506 can be between 1 microsecond and 10 milliseconds. The first power level is illustrated to be greater than the second power level. In some embodiments, the first power level can be between 1 and 4,000 Watts and the second power level can be between 1 and 500 Watts.

The first input 512 and the third input 516 are not delivered to the processing region 106 during the second period of time 508. The second input 514 is delivered to the processing region 106 at a first power level for a first portion of the second period of time 508, and the second input 514 is delivered to the processing region 106 at a second power level for a second portion of the second period of time 508. In some embodiments, the first portion of the second period of time 508 can be between 1 microsecond and 10 milliseconds long and the second portion of the second period of time 508 can be between 1 microsecond and 10 milliseconds long. The second power level is illustrated to be greater than the first power level. In some embodiments, the first power level can be between 1 and 10,000 Watts and the second power level can be between 1 and 10,000 Watts. The second input 514 is delivered to the processing region 106 at the first power level between t2 and t3, and the second input 514 is delivered to the processing region 106 at the second power level between t3 and t4.

The first input 512 and the second input 514 are not delivered to the processing region 106 during the third period of time 510. The third input 516 is delivered to the processing region 106 during the third period of time 510. The delivery of the third input 516 to the processing region 106 is halted (e.g., by the controller 142) at t5.

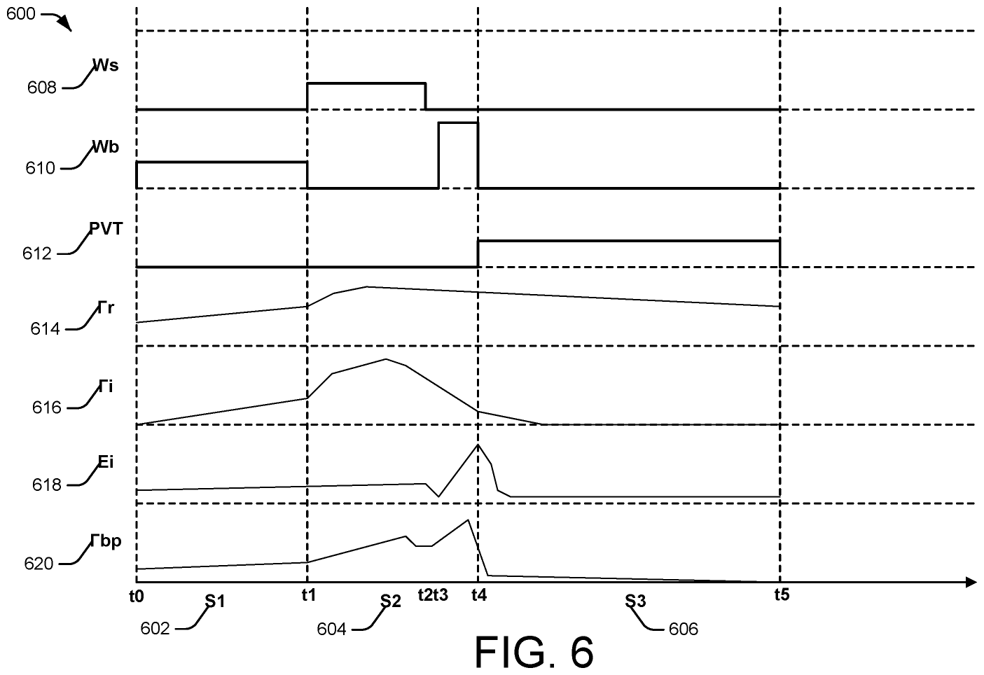

FIG. 6 illustrates a graph 600 of example inputs for controlling plasma processing during periods of time and corresponding example effects of controlling the plasma processing during the periods of time. The x-axis of the graph 600 includes a first period of time 602, a second period of time 604, and a third period of time 606. In some embodiments, the first period of time 602 may correspond to a plasma and radical generation step of a plasma assisted etching process; the second period of time 604 can correspond to an etching step of the plasma assisted etching process; and the third period of time 606 may correspond to a byproduct removal and surface pretreatment step of the plasma assisted etching process. As shown, the first period of time 602 begins at t0 and ends at t1. The second period of time 604 begins at t1 and ends at t4. The third period of time 606 begins at t4 and ends at t5. In one or more embodiments, the first period of time 602, the second period of time 604, and the third period of time 606 can be repeated one or more times (e.g., in a loop).

The y-axis of the graph 600 includes a first input 608 that represents the first radio frequency (RF) signal delivered by the source RF generator 120 to the processing region 106 (e.g., to the RF coil 118). The y-axis of the graph also includes a second input 610 which represents the second RF signal delivered by the bias RF generator 126 to the processing region 106 (e.g., to the first electrode 140). The y-axis of the graph 600 additionally includes and a third input 612 that represents the pulsed voltage waveform (e.g., PV waveform 195) delivered from the voltage source (e.g., the waveform generator 134 and the high voltage DC supply 132) to the processing region 106 (e.g., to the chucking electrode 124).

The y-axis of the graph 600 further includes a radical flux 614 in the plasma processing chamber 102, an ion flux 616 in the plasma processing chamber 102, an ion energy 618 in the plasma processing chamber 102, and a byproduct flux 620 in the plasma processing chamber 102. During the first period of time 602, the second input 610 is delivered to the processing region 106. The first input 608 and the third input 612 are not delivered to the processing region 106 during the first period of time 602. Due to the delivery of the second RF signal within the second input 610 to the first electrode 140, during the first period of time 602, the radical flux 614 increases by a relatively small amount and the ion flux 616 increases by a moderate amount. The ion energy 618 and the byproduct flux 620 each remain relatively low during the first period of time 602.

The first input 608 is delivered to the processing region 106 during a first portion of the second period of time 604, and the first input 608 is not delivered to the processing region 106 during a second portion of the second period of time 604. For example, the first input 608 is delivered to the processing region 106 between t1 and t2, and then the delivery of the first input 608 to the processing region 106 is halted (e.g., by the controller 142). The second input 610 is not delivered to the processing region 106 during a first portion of the second period of time 604, and the second input 610 is delivered to the processing region 106 during a second portion of the second period of time 604. As shown in the graph 600, the second input 610 is delivered to the processing region 106 between t3 and t4. In some embodiments, the first portion of the second period of time 604 can be between 1 microsecond and 10 milliseconds long and the second portion of the second period of time 604 can be between 1 microsecond and 10 milliseconds long. The third input 612 is not delivered to the processing region 106 during the second period of time 604.

Due to the delivery of the first RF signal within the first input 608 to the first RF coil 108 during the first portion of time and the delivery of the second input 610 to the first electrode 140 during the second portion of time, during the second period of time 604, the radical flux 614 increases by a first relatively small amount and then decreases by a second relatively small amount. The ion flux 616 increases by a first relatively large amount and then decreases by a second relatively large amount during the second period of time 604. Additionally, during the second period of time 604, the ion energy 618 remains relatively low until around t2 where the ion energy 618 decreases by a relatively small amount. Around t3, the ion energy 618 increases by a relatively large amount. During the second period of time 604, the byproduct flux 620 initially increases by a first moderate amount, decreases by a relatively small amount just before t2, flattens between t2 and t3, increases by a second moderate amount, and then decreases by a third moderate amount.

During the third period of time 606, the third input 612 is delivered to the processing region 106 (e.g., the chucking electrode 124). The first input 608 and the second input 610 are not delivered to the processing region 106 during the third period of time 606. The radical flux 614 decreases by a relatively small amount and the ion flux 616 also decreases by a relatively small amount during the third period of time 606. The ion energy 618 decreases by a relatively large amount and the byproduct flux 620 decreases by a moderate amount during the third period of time 606.

In some embodiments, deliveries and halting deliveries of the inputs 608, 610, 612 illustrated in the graph 600 may be configured to enhance chemical reactions and improve selectivity during the plasma assisted etching process. For example, the period of time between t1 and t3 may be configured to enhance adsorption and surface pretreatment during the plasma assisted etching process. In various embodiments, the period of time between t3 and t4 may be configured to enhance etching during the plasma assisted etching process.

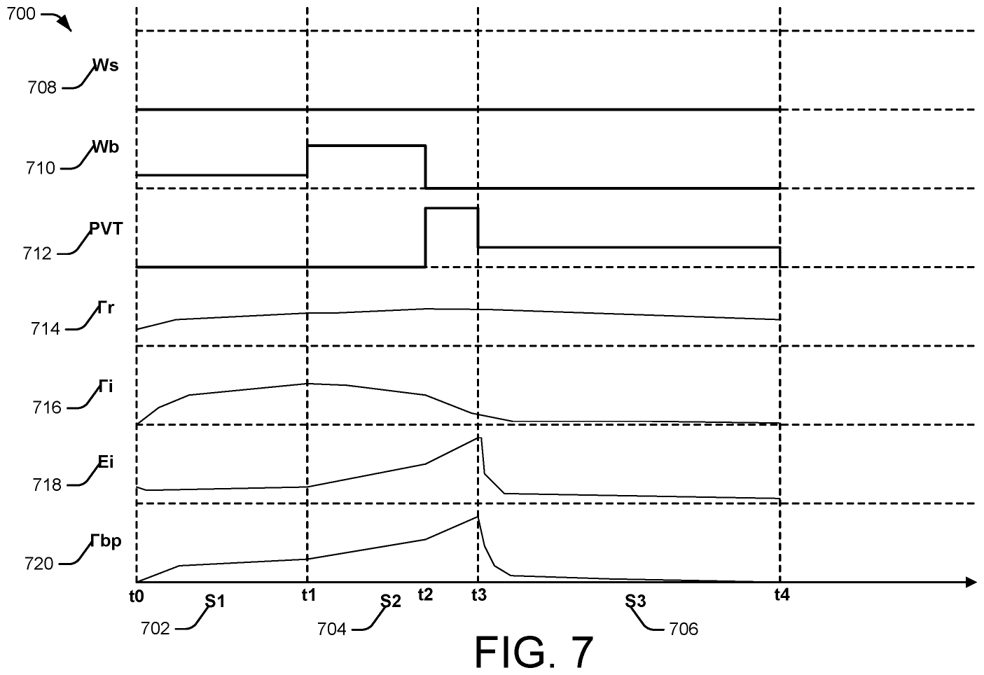

FIG. 7 illustrates a graph 700 of example inputs for controlling plasma processing during periods of time and corresponding example effects of controlling the plasma processing during the periods of time. The x-axis of the graph 700 includes a first period of time 702, a second period of time 704, and a third period of time 706. The first period of time 702 begins at t0 and ends at t1, the second period of time 704 begins at t1 and ends at t3, and the third period of time 706 begins at t3 and ends at t4. The y-axis of the graph 700 includes a first input 708, a second input 710, and a third input 712. The first input 708 represents the first radio frequency (RF) signal delivered by the source RF generator 120 to the processing region 106 (e.g., to the RF coil 118). Notably, as shown in the graph 700, the first input 708 is not delivered to the processing region 106 during the first period of time 702, the second period of time 704, or the third period of time 706.

The second input 710 represents the second RF signal delivered by the bias RF generator 126 to the processing region 106 (e.g., to the first electrode 140). The third input 712 represents the pulsed voltage waveform (e.g., PV waveform 195) delivered from the voltage source (e.g., the waveform generator 134 and the high voltage DC supply 132) to the processing region 106 (e.g., to the chucking electrode 124). The y-axis of the graph 700 also includes a radical flux 714 in the plasma processing chamber 102, an ion flux 716 in the plasma processing chamber 102, an ion energy 718 in the plasma processing chamber 102, and a byproduct flux 720 in the plasma processing chamber 102.

During the first period of time 702, the second input 710 is delivered to the processing region 106 (e.g., the first electrode 140) at a first power level. The third input 712 is not delivered to the processing region 106 during the first period of time 702. Due to the delivery of the second RF signal within the second input 710 to the first electrode 140, during the first period of time 702, the radical flux 714 increases by a relatively small amount and the ion flux 716 increases by a moderate amount. The ion energy 718 remains relatively low during the first period of time 602 without significantly increasing or decreasing. As shown, the byproduct flux 720 increases by as relatively small amount but remains relatively low during the first period of time 702.

The second input 710 is delivered to the processing region 106 at a second power level during a first portion of the second period of time 704, and the second input 710 is not delivered to the processing region 106 during a second portion of the second period of time 704. For example, the second input 710 is delivered to the processing region 106 at the second power level between t1 and t2. At t2, delivery of the second input 710 to the processing region 106 is halted (e.g., by the controller 142).

The third input 712 is not delivered to the processing region 106 during the first portion of the second period of time 704, and the third input 712 is delivered to the processing region 106 at a first power level during the second portion of the second period of time 704. Due to the delivery of the second RF signal within the second input 710 to the first electrode 140, during the first portion of the second period of time 704, the radical flux 714 remains relatively flat and the ion flux 716 decreases slightly. The ion energy 718 and the byproduct flux 720 each increase at a relatively constant rate during the first portion of the second period of time 704.

As shown, the third input 712 is delivered to the processing region 106 at the first power level between t2 and t3. In some embodiments, the first portion of the second period of time 704 can be between 1 microsecond and 10 milliseconds long and the second portion of the second period of time 704 can be between 1 microsecond and 10 milliseconds long. During the second portion of the second period of time 704, due to the delivery of the voltage waveform within the third input 712 to the chucking electrode 124, the radical flux 714 remains relatively flat but the ion flux 716 decreases by a relatively large amount. The ion energy 718 and the byproduct flux 720 each increase a moderate amount during the second portion of the second period of time 704 but at a faster rate than the increase during the first portion of the second period of time 704.

The third input 712 is delivered to the processing region 106 at a second power level during the third period of time 706. The second input 710 is not delivered to the processing region 106 during the third period of time 706. Due to the delivery of the voltage waveform within the third input 712 to the chucking electrode 124, during the third period of time 706, the radical flux 714 remains relatively flat but decreases slightly. The ion flux 716 decreases by a small amount and remains relatively low during the third period of time 706. However, the ion energy 718 and the byproduct flux 720 each decrease by a relatively large amount and remain relatively low during the third period of time 706.

It is to be appreciated that in the graph 700, the second input 710 and the third input 712 may be synchronous. It is also to be appreciated that in the graph 700, the second input 710 and the third input 712 can be asynchronous. Notably, the first input 708, the second input 710, and the third input 712 can have selected power levels, duty cycles, and/or offsets. Furthermore, it is to be appreciated that a synchronization master can be implemented using the source RF generator 120, the bias RF generator 126, or the voltage source (e.g., the waveform generator 134 and the high voltage DC supply 132).

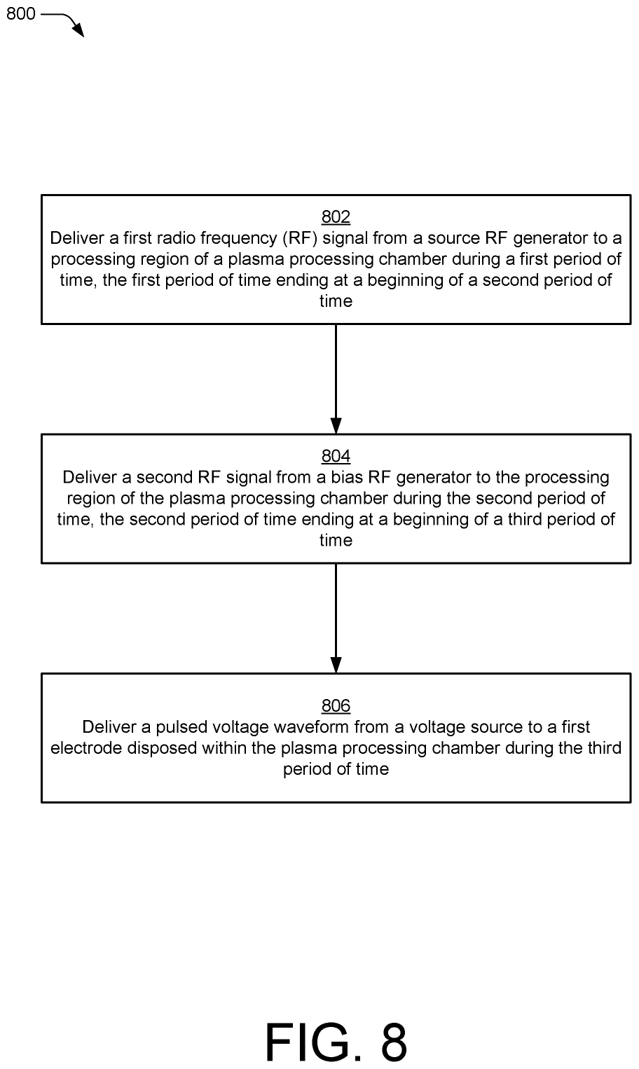

FIG. 8 is a flow diagram illustrating a method 800 for plasma processing. At 802, a first radio frequency (RF) signal is delivered from a source RF generator to a processing region of a plasma processing chamber during a first period of time, the first period of time ending at a beginning of a second period of time. In some embodiments, the controller 142 causes the source RF generator 120 to deliver the first RF signal to the processing region 106 of the plasma processing chamber 102 during the first period of time. For example, the source RF generator 120 delivers the first RF signal to the RF coil 118 during the first period of time.

At 804, a second RF signal is delivered from a bias RF generator to the processing region of the plasma processing chamber during the second period of time, the second period of time ending at a beginning of a third period of time. In one or more embodiments, the controller 142 causes the bias RF generator 126 to deliver the second RF signal to the processing region 106 of the plasma processing chamber 102 during the second period of time. In some examples, the bias RF generator 126 delivers the second RF signal to the first electrode 140 during the second period of time.

At 806, a pulsed voltage waveform is delivered from a voltage source to a first electrode disposed within the plasma processing chamber during the third period of time. In various embodiments, the controller 142 causes the voltage source (e.g., the waveform generator 134 and the high voltage DC supply 132) to deliver the pulsed voltage waveform to the processing region 106 of the plasma processing chamber 102 during the third period of time. In one or more examples, the voltage source delivers the pulsed voltage waveform to the chucking electrode 124 during the third period of time.

### ADDITIONAL CONSIDERATIONS

In the above description, details are set forth by way of example to facilitate an understanding of the disclosed subject matter. It should be apparent to a person of ordinary skill in the field, however, that the disclosed implementations are exemplary and not exhaustive of all possible implementations. Thus, it should be understood that reference to the described examples is not intended to limit the scope of the disclosure. Any alterations and further modifications to the described devices, instruments, methods, and any further application of the principles of the present disclosure are fully contemplated as would normally occur to one skilled in the art to which the disclosure relates. In particular, it is fully contemplated that the features, components, and/or steps described with respect to one implementation may be combined with the features, components, and/or steps described with respect to other implementations of the present disclosure. As used herein, the term “about” may refer to a +/−10% variation from the nominal value. It is to be understood that such a variation can be included in any value provided herein.

As used herein, “a processor,” “at least one processor” or “one or more processors” generally refers to a single processor configured to perform one or multiple operations or multiple processors configured to collectively perform one or more operations. In the case of multiple processors, performance of the one or more operations could be divided amongst different processors, though one processor may perform multiple operations, and multiple processors could collectively perform a single operation. Similarly, “a memory,” “at least one memory” or “one or more memories” generally refers to a single memory configured to store data and/or instructions, multiple memories configured to collectively store data and/or instructions.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

While the foregoing is directed to embodiments of the present disclosure, other and further embodiments of the disclosure may be devised without departing from the basic scope thereof, and the scope thereof is determined by the claims that follow.

We claim:

1. A method for plasma processing, comprising:
delivering a first radio frequency (RF) signal from a source RF generator to a processing region of a plasma processing chamber during a first period of time, the first period of time ending at a beginning of a second period of time;
delivering a second RF signal from a bias RF generator to the processing region of the plasma processing chamber during the second period of time, the second period of time ending at a beginning of a third period of time; and
delivering a pulsed voltage waveform from a voltage source to a first electrode disposed within the plasma processing chamber during the third period of time.

2. The method of claim 1, wherein the second RF signal is delivered to a second electrode disposed within a substrate support of the plasma processing chamber.

3. The method of claim 2, wherein the first electrode is disposed within the substrate support of the plasma processing chamber.

4. The method of claim 3, wherein the first RF signal is delivered to a coil.

5. The method of claim 1, wherein the first RF signal is delivered to a coil.

6. The method of claim 1, further comprising halting the delivery of the first RF signal from the source RF generator at the beginning of the second period of time, and halting the delivery of the second RF signal from the bias RF generator at the beginning of the third period of time.

7. The method of claim 1, wherein the first period of time, the second period of time, and the third period of time are repeated one or more times.

8. The method of claim 1, wherein the first RF signal is provided at a first power level for a first portion of the first period of time and at a second power level for a second portion of the first period of time.

9. The method of claim 1, wherein the second RF signal is provided at a first power level for a first portion of the second period of time and at a second power level for a second portion of the second period of time.

10. The method of claim 1, further comprising delivering the second RF signal before the beginning of the second period of time.

11. The method of claim 1, further comprising halting the delivery of the first RF signal from the source RF generator after the beginning of the second period of time.

12. A non-transitory computer readable medium storing executable instructions that, when executed by at least one processor, cause the at least one processor to perform operations comprising:
delivering a first radio frequency (RF) signal from a source RF generator to a processing region of a plasma processing chamber during at least a portion of a first period of time, the first period of time ending at a beginning of a second period of time;
delivering a second RF signal from a bias RF generator to the processing region of the plasma processing chamber during at least a portion of the second period of time, the second period of time ending at a beginning of a third period of time; and
delivering a pulsed voltage waveform from a voltage source to a first electrode disposed in the plasma processing chamber during the third period of time.

13. The non-transitory computer readable medium of claim 12, wherein the first RF signal is delivered to a coil.

14. The non-transitory computer readable medium of claim 12, wherein the second RF signal is delivered to a second electrode disposed within a substrate support of the plasma processing chamber.

15. The non-transitory computer readable medium of claim 14, wherein the first electrode is disposed within the substrate support of the plasma processing chamber.

16. The non-transitory computer readable medium of claim 12, wherein the first period of time, the second period of time, and the third period of time are repeated one or more times.

17. The non-transitory computer readable medium of claim 12, wherein the first RF signal is provided at a first power level for a first portion of the first period of time and at a second power level for a second portion of the first period of time.

18. The non-transitory computer readable medium of claim 12, wherein the second RF signal is provided at a first power level for a first portion of the second period of time and at a second power level for a second portion of the second period of time.

19. The non-transitory computer readable medium of claim 12, wherein the operations further comprise delivering the second RF signal before the beginning of the second period of time.

20. The non-transitory computer readable medium of claim 12, wherein the operations further comprise halting the delivery of the first RF signal from the source RF generator after the beginning of the second period of time, and halting the delivery of the second RF signal from the bias RF generator at the beginning of the third period of time.
